(19) United States
(12) Patent Application Publication
(10) Pub. No.: US 2021/0408497 A1
(43) Pub. Date: Dec. 30, 2021

(54) POLARIZING PLATE FOR OLED AND DISPLAY DEVICE COMPRISING THE SAME

(71) Applicant: DONGWOO FINE-CHEM CO., LTD., Iksan-si (KR)

(72) Inventors: Dongduk CHOI, Bucheon-si (KR); Ji Hoon KIM, Hwaseong-si (KR); In Sub HWANG, Jincheon-gun (KR)

(73) Assignee: DONGWOO FINE-CHEM CO., LTD., Iksan-si (KR)

(21) Appl. No.: 17/356,930

(22) Filed: Jun. 24, 2021

(30) Foreign Application Priority Data
Jun. 25, 2020 (KR) 10-2020-0077929

(51) Int. Cl. H01L 51/52; G02B 5/30

(52) U.S. Cl. CPC H01L 51/5281; G02B 5/3083; H01L 51/5253

(57) ABSTRACT

A polarizing plate and a display device including the polarizing plate are disclosed. The polarizing plate is suitable for OLED and contains a polarizer, a moisture barrier layer, and a retardation layer, which are sequentially laminated. The moisture barrier layer is disposed on the opposite side of the viewing side of the polarizer and has a water vapor transmission rate of 450 g/m²·24 hr or less. The retardation layer comprises a λ/4 retardation layer, and a display device comprising the same. The polarizing plate can be made thinner, prevent reverse curling, suppress migration of iodine in a polarizer to prevent corrosion of a metal electrode of a lower panel, facilitate post-treatment such as polarizer bleaching, and prevent retardation changes even in a high-humidity environment.

### CROSS REFERENCE TO RELATED APPLICATIONS

This application claims priority based on Korean Patent Application No. 10-2020-0077929, filed Jun. 25, 2020, the content of which is incorporated herein by reference in its entirety.

### TECHNICAL FIELD

The present invention relates to a polarizing plate for OLED and a display device comprising the same. Particularly, the present invention relates to a polarizing plate for OLED which can be made thinner, prevent reverse curling, suppress migration of iodine in a polarizer to prevent corrosion of a metal electrode of a lower panel, facilitate post-treatment such as polarizer bleaching, and prevent retardation changes even in a high-humidity environment, and a display device comprising the same.

### BACKGROUND ART

Organic light-emitting diode (OLED) panels may reflect external light such as sunlight and lighting, due to exposure of electrodes. Therefore, in the organic light-emitting diode (OLED) panel, the reflected external light may lower visibility and contrast ratio, which may deteriorate display quality.

Accordingly, in order to block reflection of external light on the surface in a power-off state and have black visibility, Korean Patent Application Publication No. 2009-0122138 has proposed attaching a circular polarizing plate having a linear polarizer combined with a λ/4 retardation layer on the viewing side of the OLED panel.

Recently, as display devices become thinner, there has been a need for thinner polarizing plates. In addition, according to the need of the thinning, there is a trend to eliminate a passivation layer which prevents ITO of OLED panels from corrosion. Therefore, it is necessary to block the migration of iodine from the polarizer to the panel to prevent corrosion of ITO.

Meanwhile, as the polarizing plates are required to be handled, it is desirable to suppress curls as much as possible. In the case of polarizing plate having curls, especially having reverse curls, process problems such as generation of bonding bubbles occur when it is attached to the panel.

Further, when a polarizing plate is disposed on parts of a display device such as a camera, bleaching is required to improve visibility of the camera lens. Therefore, there has been a need for development of a polarizing plate which can be easily post-treated.

### DISCLOSURE

### Technical Problem

It is an object of the present invention to provide a polarizing plate for OLED which can be made thinner, prevent reverse curling, suppress migration of iodine in a polarizer to prevent corrosion of a metal electrode of a lower panel, facilitate post-treatment such as polarizer bleaching, and prevent retardation changes even in a high-humidity environment.

It is another object of the present invention to provide a display device comprising the polarizing plate for OLED.

### Technical Solution

In one aspect, the present invention provides a polarizing plate for OLED in which a polarizer, a moisture barrier layer and a retardation layer are sequentially laminated, wherein the moisture barrier layer is disposed on the opposite side of the viewing side of the polarizer, and has a water vapor transmission rate of 450 g/m²·24 hr or less; and

the retardation layer comprises a λ/4 retardation layer.

In one embodiment of the present invention, the moisture barrier layer may be at least one film selected from the group consisting of: a cyclic olefin polymer film with or without at least one of a hard coating layer or a UV curable adhesive layer formed on at least one side thereof; an acrylic film with or without at least one of a hard coating layer or a UV curable adhesive layer formed on at least one side thereof; and a triacetyl cellulose film with at least one of a hard coating layer or a UV curable adhesive layer formed on at least one side thereof.

In one embodiment of the present invention, an in-plane retardation (Ro) of the moisture barrier layer may be 10 nm or less.

In one embodiment of the present invention, an out-of-plane retardation (Rth) of the moisture barrier layer may be 40 nm or less.

In one embodiment of the present invention, the retardation layer may be a λ/4 retardation layer; a retardation layer in which a λ/2 retardation layer and a λ/4 retardation layer are laminated sequentially from the viewing side; or a retardation layer in which a λ/4 retardation layer and a positive C plate layer are laminated sequentially from the viewing side.

In one embodiment of the present invention, the moisture barrier layer and the retardation layer may be attached via a pressure-sensitive adhesive (PSA)/adhesive layer.

In one embodiment of the present invention, a pressure-sensitive adhesive layer may be further laminated on the opposite side of the viewing side of the retardation layer.

In one embodiment of the present invention, a releasable protective film may be laminated on the viewing side of the polarizer.

In one embodiment of the present invention, a release film may be further laminated on the opposite side of the viewing side of the pressure-sensitive adhesive layer.

In another aspect, the present invention provides a display device comprising the polarizing plate for OLED; and an OLED panel laminated on the opposite side of the viewing side of the polarizing plate for OLED.

In still another aspect, the present invention provides a display device comprising the polarizing plate for OLED; an OLED panel laminated on the opposite side of the viewing side of the polarizing plate for OLED; and a cover window attached on the viewing side of the polarizing plate for OLED via a transparent adhesive layer.

### Advantageous Effects

The polarizing plate for OLED according to the present invention can be made thinner, prevent reverse curling, suppress migration of iodine in a polarizer to prevent corrosion of a metal electrode of a lower panel, facilitate post-treatment such as polarizer bleaching, and prevent retardation changes even in a high-humidity environment.

### BRIEF DESCRIPTION OF DRAWINGS

FIGS. 1 to 5 are cross-sectional views schematically illustrating the polarizing plate for OLED according to one embodiment of the present invention.

FIG. 6 is a cross-sectional view schematically illustrating the display device according to one embodiment of the present invention.

### BEST MODE

Hereinafter, the present invention will be described in more detail.

The present invention relates to a polarizing plate for OLED having a structure in which a moisture barrier layer is laminated only on the opposite side of the viewing side of a polarizer while having no moisture barrier layer on the viewing side, so that the polarizer is exposed as an outmost layer if a protective film of the polarizer is released.

The polarizing plate for OLED according to the present invention has a moisture barrier layer only on the opposite side of the viewing side of a polarizer, and thus the polarizing plate can be made thinner. Further, as the polarizing plate for OLED according to the present invention has a structure in which a moisture barrier layer is laminated on the opposite side of the viewing side of the polarizer, migration of iodine from the polarizer to a lower panel can be suppressed to prevent corrosion of a metal electrode of the lower panel. Also, reverse curling of the polarizing plate can be prevented by shrinkage of the polarizer under a dry atmosphere, and retardation changes can be prevented even in a high-humidity environment. Under the dry atmosphere, the polarizer is shrunken in the length direction, but layers disposed under the moisture barrier layer have lower dimensional change than that of the polarizer, since the moisture barrier layer blocks the moisture. Accordingly, a difference in length occurs between the polarizer and the moisture barrier layer, and at this time, since the polarizer and the moisture barrier layer are fixed through interlayer adhesion, a forward curling in the direction of the viewing side is induced, so that a reverse curling in the opposite direction of the viewing side can be prevented. Therefore, it is possible to prevent the generation of bonding bubbles or misalignment when the polarizing plate is adhered to a panel.

Further, since the polarizing plate for OLED according to the present invention has no moisture barrier layer on the viewing side of the polarizer, post-treatments such as polarizer bleaching are easy.

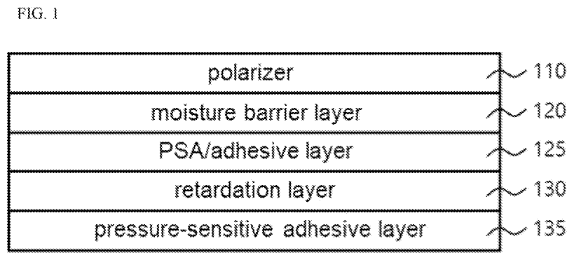

FIG. 1 is a cross-sectional view schematically illustrating the polarizing plate for OLED according to one embodiment of the present invention.

Referring to FIG. 1, the polarizing plate for OLED according to one embodiment of the present invention comprises a polarizer 110, a moisture barrier layer 120 and a retardation layer 130.

The polarizer 110 is prepared by dyeing a hydrophilic polymer film with iodine or a dichroic dye followed by aligning. As the hydrophilic polymer film, a polyvinyl alcohol-based film, a partially saponified polyvinyl alcohol-based film and the like may be used.

The degree of polymerization of the polyvinyl alcohol-based film may be typically 500 to 10,000, preferably 1,000 to 6,000, more preferably 1,400 to 4,000. In the case of the saponified polyvinyl alcohol-based film, the degree of saponification may be preferably 95.0 mol % or more, more preferably 99.0 mol % or more, even more preferably 99.9 mol % or more in terms of solubility.

The type of the hydrophilic polymer film is not particularly limited to the polyvinyl alcohol-based film, as long as the film can be dyed with iodine or a dichroic dye. For example, a hydrophilic polymer film such as a polyethylene terephthalate film, an ethylene-vinyl acetate copolymer film, an ethylene-vinyl alcohol copolymer film, a cellulose film and a partially saponified film thereof; and a polyene alignment film such as a dehydration-treated polyvinyl alcohol-based film and a dehydrochlorination-treated polyvinyl chloride may be used.

The thickness of the polarizer 110 is not particularly limited, but may be, for example, in the range of 2 to 40 μm, preferably in the range of 2 to 30 μm, more preferably in the range of 5 to 10 μm. When the thickness of the polarizer 110 is within the above range, the thinning of the polarizing plate is possible, and shrinkage force due to the shrinkage/expansion of the polarizer in a dry/humid environment can be reduced, thereby minimizing the occurrence of curls.

The moisture barrier layer 120 is attached on the polarizer 110 so as to be disposed on the opposite side of the viewing side of the polarizer.

The moisture barrier layer 120 is a film having low moisture permeability and has a water vapor transmission rate of 450 g/m²·24 hr or less, for example 0.1 to 450 g/m²·24 hr.

The water vapor transmission rate represents the amount of water vapor passing through a layer per unit area and unit time.

The water vapor transmission rate is a value measured by adding water vapor under the condition of a temperature of 40° C. and a relative humidity of 90% for 24 hours.

If the water vapor transmission rate of the moisture barrier layer 120 exceeds 450 g/m²·24 hr, it is difficult to prevent migration of iodine from the polarizer to the lower panel, and reverse curling of the polarizing plate may occur.

The moisture barrier layer 120 is a low retardation layer having an in-plane retardation (Ro) of 10 nm or less. If the in-plane retardation (Ro) of the moisture barrier layer 120 exceeds 10 nm, the frontal reflection color may be changed from neutral black to blue or red, and light leakage may occur.

The moisture barrier layer 120 may have an out-of-plane retardation (Rth) of 40 nm or less. If the out-of-plane retardation (Rth) of the moisture barrier layer 120 exceeds 40 nm, the diagonal reflection color may be changed from neutral black to blue or red.

As the moisture barrier layer 120, an appropriate film having low moisture permeability may be used in consideration of the water vapor transmission rate and retardation. For example, as the moisture barrier layer 120, a cyclic olefin polymer (COP) film with or without at least one of a hard coating layer or a UV curable adhesive layer formed on at least one side thereof; an acrylic film with or without at least one of a hard coating layer or a UV curable adhesive layer formed on at least one side thereof; a triacetyl cellulose (TAC) film with at least one of a hard coating layer or a UV curable adhesive layer formed on at least one side thereof; and the like may be used, and these may be used alone or in combination of two or more.

Since a TAC film has a water vapor transmission rate of 1,000 g/m²·24 hr or more, it is used in the form having at least one of a hard coating layer or a UV curable adhesive layer formed on at least one side thereof. In this case, the hard coating layer may be disposed on either the viewing side of the TAC film or the opposite side thereof. The UV curable adhesive layer may be disposed on the viewing side of the TAC film, thereby lowering the water vapor transmission rate of the TAC film, while attaching the TAC film to the polarizer.

For example, the TAC film with at least one of a hard coating layer or a UV curable adhesive layer formed on at least one side thereof may have a structure in which a UV curable adhesive layer and a TAC film are laminated sequentially from the viewing side; a structure in which a UV curable adhesive layer, a TAC film and a hard coating layer are laminated sequentially from the viewing side; a structure in which a TAC film and a hard coating layer are laminated sequentially from the viewing side; a structure in which a hard coating layer and a TAC film are laminated sequentially from the viewing side; and the like.

The cyclic olefin polymer (COP) film and the acrylic film have a water vapor transmission rate of 450 g/m²·24 hr or less, and thus they can be used for the moisture barrier layer 120 without an additional hard coating layer or UV curable adhesive layer. However, if necessary, the cyclic olefin polymer (COP) film and the acrylic film may have a hard coating layer and/or UV curable adhesive layer.

The hard coating layer may be formed using a hard coating composition commonly used in the art.

The hard coating composition may comprise a light transmittable resin, a photoinitiator and a solvent.

The light transmittable resin is a photocurable resin, which may comprise a photocurable (meth)acrylate oligomer and/or monomer.

As the photocurable (meth)acrylate oligomer, an epoxy (meth)acrylate, a urethane (meth)acrylate and the like may be used.

The monomer can be used without limitation as long as it is commonly used in the art, and monomers having an unsaturated group as a photocurable functional group in the molecule are preferred, wherein the unsaturated group may be a (meth)acryloyl group, a vinyl group, a styryl group, an allyl group and the like.

The photoinitiator is capable of forming radicals by irradiation with light, and can be used without limitation as long as it is used in the art. For example, hydroxy ketones, amino ketones, hydrogen abstraction type photoinitiators and the like may be used.

The solvent can be used without limitation as long as it is used in the art. For example, alcohols, ketones, acetates, hexanes, benzenes, ethers and the like may be used.

In addition to the above-mentioned components, the hard coating composition may further comprise components commonly used in the art, such as leveling agents, UV stabilizers, heat stabilizers, antioxidants, surfactants, lubricants, antifouling agents and the like.

The hard coating layer can be prepared by applying and curing the hard coating composition.

The thickness of the hard coating layer is not particularly limited, and for example, may be 1 to 30 μm, preferably 3 to 20 μm. When the thickness of the hard coating layer is within the above range, the water vapor transmission rate can be controlled to 450 g/m²·24 hr or less, and excellent hardness and bending resistance can be obtained.

The UV curable adhesive layer can be formed using a UV curable adhesive commonly used in the art.

Examples of the UV curable adhesive may include an adhesive using radical photopolymerization such as a (meth)acrylate-based adhesive, an ene/thiol-based adhesive, an unsaturated polyester-based adhesive and the like; or an adhesive using cationic photopolymerization such as an epoxy-based adhesive, an oxetane-based adhesive, an epoxy/oxetane-based adhesive, a vinyl ether-based adhesive and the like.

The thickness of the UV curable adhesive layer is not particularly limited, and for example, may be 0.01 to 10 μm, preferably 0.5 to 5 μm. When the thickness of the UV curable adhesive layer is within the above range, the water vapor transmission rate can be controlled to 450 g/m²·24 hr or less, and excellent adhesiveness and bending resistance can be obtained.

The moisture barrier layer 120 can be attached on the polarizer 110 via an adhesive layer (not shown). At this time, when the moisture barrier layer 120 is a film having low moisture permeability where an UV curable adhesive layer is formed, a separate adhesive layer may not be required.

The adhesive layer can be formed using a water-based adhesive or an UV curable adhesive.

The water-based adhesive is an adhesive in which adhesive components are dissolved or dispersed in water. The water-based adhesive may comprise a polyvinyl alcohol-based resin or a urethane resin as a main component and a crosslinking agent or a curable compound such as an isocyanate-based compound or an epoxy compound to improve adhesiveness.

As the UV curable adhesive, the same as that described above may be used.

The thickness of the adhesive layer is not particularly limited, and for example, may be 0.01 to 10 μm, preferably 0.5 to 5 μm. When the thickness of the adhesive layer is within the above range, excellent adhesiveness and bending resistance can be obtained.

The thickness of the moisture barrier layer 120 is in the range of 5 to 60 μm, preferably 5 to 50 μm, more preferably 10 to 40 μm. If the thickness of the moisture barrier layer 120 is less than 5 μm, peeling or cracking may easily occur during the manufacturing or handling of the polarizing plate, and if the thickness exceeds 60 μm, it may be difficult to attain the thinning of the polarizing plate.

The retardation layer 130 is laminated on the opposite side of the viewing side of the moisture barrier layer 120.

The retardation layer 130 may be, for example, a stretched or unstretched polymer film, or a liquid crystal layer formed by curing a reactive mesogen.

For example, in the case that the retardation layer 130 is made of a liquid crystal layer, a reactive mesogen (RM) which is a liquid crystal compound having optical anisotropy and crosslinking property by light or heat may be used.

The retardation layer 130 comprises a λ/4 retardation layer.

The λ/4 retardation layer can convert incident linearly polarized light to elliptically polarized light or circularly polarized light, or conversely, can convert incident elliptically polarized light or circularly polarized light to linearly polarized light. Accordingly, the λ/4 retardation layer can be applied to an OLED panel to prevent reflection of external light, and thus it is possible to implement black visibility in a power-off state.

The retardation layer 130 may have a single-layer structure or a multi-layer structure in which 2 or more layers are laminated. When the retardation layer 130 has a single-layer structure, the retardation layer 130 may consist of a λ/4 retardation layer. When the retardation layer 130 has a multi-layer structure, the retardation layer 130 essentially comprises a λ/4 retardation layer, and may further comprise at least one of a λ/2 retardation layer or a positive C plate layer. Herein, each layer may be attached via a pressure-sensitive adhesive or an adhesive, or may be laminated each other by direct coating. The λ/2 retardation layer and the positive C plate layer can be used to improve black visibility of the reflection color.

As the pressure-sensitive adhesive (PSA) or the adhesive, various PSAs or adhesives well known in the art may be used without particular limitation.

For example, as the pressure-sensitive adhesive (PSA), a rubber-based PSA, an acrylic-based PSA, a silicone-based PSA, a urethane-based PSA, a polyvinyl alcohol-based PSA, a polyvinylpyrrolidone-based PSA, a polyacrylamide-based PSA, a cellulose-based PSA, a vinyl alkyl ether-based PSA and the like may be used.

Also, as the adhesive, a photocurable adhesive may be exemplified, but the type of the adhesive is not particularly limited.

The photocurable adhesive is crosslinked and cured by active energy rays such as ultraviolet (UV) and electron beam (EB) to exhibit strong adhesion, and may comprise a reactive oligomer, a reactive monomer, a photopolymerization initiator and the like.

The reactive oligomer is an important component which determines the properties of the adhesive, and forms a polymer bond by photopolymerization to form a cured film. As the reactive oligomer, a polyester-based resin, a polyether-based resin, a polyurethane-based resin, an epoxy-based resin, a polyacrylic-based resin, a silicone-based resin and the like can be used.

The reactive monomer serves as a crosslinking agent and a diluent for the reactive oligomer described above and affects adhesion properties. As the reactive monomer, a monofunctional monomer, a polyfunctional monomer, an epoxy-based monomer, vinyl ethers, cyclic ethers and the like can be used.

The photopolymerization initiator initiates photopolymerization by absorbing light energy to generate radicals or cations, and a suitable one may be selected and used depending on the photopolymerization resin.

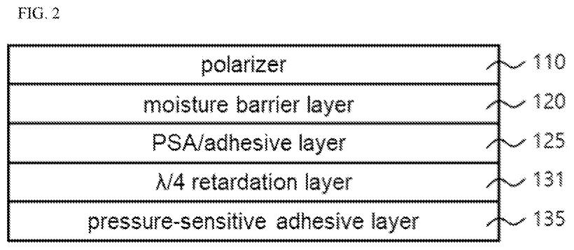

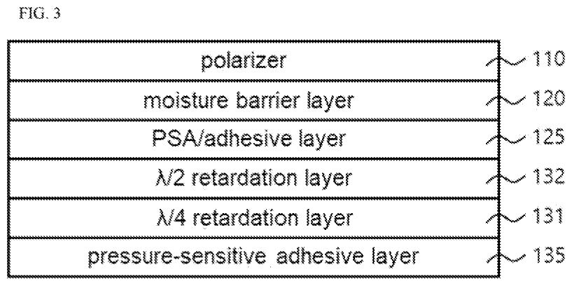

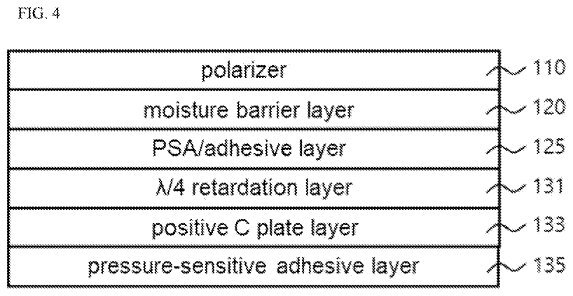

For example, referring to FIG. 2, a polarizing plate for OLED according to one embodiment of the present invention has a structure where a polarizer 110, a moisture barrier layer 120 and a λ/4 retardation layer 131 are laminated sequentially from the viewing side. Referring to FIG. 3, a polarizing plate for OLED according to one embodiment of the present invention has a structure where a polarizer 110, a moisture barrier layer 120, a λ/2 retardation layer 132 and a λ/4 retardation layer 131 are laminated sequentially from the viewing side. Referring to FIG. 4, a polarizing plate for OLED according to one embodiment of the present invention has a structure where a polarizer 110, a moisture barrier layer 120, a λ/4 retardation layer 131 and a positive C plate layer 133 are laminated sequentially from the viewing side.

In addition, the moisture barrier layer 120 and the retardation layer 130 may be attached via a pressure-sensitive adhesive (PSA)/adhesive layer 125.

The PSA/adhesive layer 125 may be formed using various PSAs or adhesives well known in the art without particular limitation.

For example, as the PSA which can be used for the PSA/adhesive layer 125, a rubber-based PSA, an acrylic-based PSA, a silicone-based PSA, a urethane-based PSA, a polyvinyl alcohol-based PSA, a polyvinylpyrrolidone-based PSA, a polyacrylamide-based PSA, a cellulose-based PSA, a vinyl alkyl ether-based PSA and the like may be used.

Also, as the adhesive which can be used for the PSA/adhesive layer 125, a photocurable adhesive may be exemplified, but the type of the adhesive is not particularly limited.

The photocurable adhesive is crosslinked and cured by active energy rays such as ultraviolet (UV) and electron beam (EB) to exhibit strong adhesion, and may comprise a reactive oligomer, a reactive monomer, a photopolymerization initiator and the like.

The reactive oligomer is an important component which determines the properties of the adhesive, and forms a polymer bond by photopolymerization to form a cured film. As the reactive oligomer, a polyester-based resin, a polyether-based resin, a polyurethane-based resin, an epoxy-based resin, a polyacrylic-based resin, a silicone-based resin and the like can be used.

The reactive monomer serves as a crosslinking agent and a diluent for the reactive oligomer described above and affects adhesion properties. As the reactive monomer, a monofunctional monomer, a polyfunctional monomer, an epoxy-based monomer, vinyl ethers, cyclic ethers and the like can be used.

The photopolymerization initiator initiates photopolymerization by absorbing light energy to generate radicals or cations, and a suitable one may be selected and used depending on the photopolymerization resin.

The thickness of the PSA/adhesive layer 125 is preferably 0.1 to 10 μm, while it is preferred to apply as thin as possible within the range which does not impair workability and durability. More preferably, the thickness is 1 to 5 μm. If the thickness of the PSA/adhesive layer 125 is less than 0.1 μm, the uniform in-plane adhesion cannot be implemented. If the thickness exceeds 10 μm, it may be difficult to attain the thinning of the polarizing plate.

The PSA/adhesive layer 125 can be formed by the method of applying the PSA and/or adhesive on any one side of the moisture barrier layer 120 or the retardation layer 130, or the method of attaching an adhesive sheet prepared by applying the PSA and/or adhesive on a release sheet followed by drying or curing to any one side of the moisture barrier layer 120 or the retardation layer 130.

A pressure-sensitive adhesive layer 135 may be further laminated on the opposite side of the viewing side of the retardation layer 130. The pressure-sensitive adhesive layer 135 attaches the polarizing plate 100 for OLED to an OLED panel 10.

The material and the formation method of the pressure-sensitive adhesive layer 135 may be the same as the pressure-sensitive adhesive used for the PSA/adhesive layer 125.

The thickness of the pressure-sensitive adhesive layer 135 is preferably 10 to 30 μm, while it is preferred to apply as thin as possible within the range which does not impair workability and durability. More preferably, the thickness is 15 to 25 μm. If the thickness of the pressure-sensitive adhesive layer 135 is less than 10 μm, it cannot fill dents or damages in the panel, so that the defects may be recognized. If the thickness exceeds 30 μm, it may be difficult to attain the thinning of the polarizing plate.

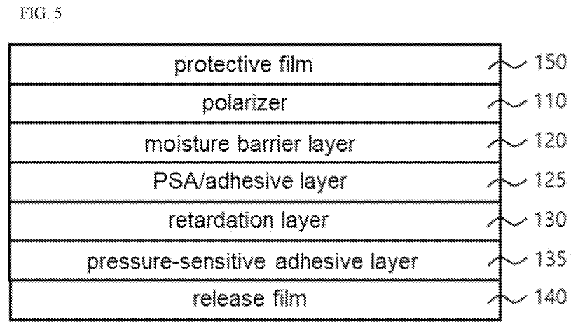

As shown in FIG. 5, the polarizing plate for OLED according to one embodiment of the present invention may have a releasable protective film 150 laminated on the viewing side of the polarizer 110.

The releasable protective film 150 comprises a substrate, and a pressure-sensitive adhesive layer formed on one side of the substrate. The pressure-sensitive adhesive layer is attached to the polarizer, and when the polarizing plate is attached to a cover window, the pressure-sensitive adhesive layer is released from the polarizer, thereby easily removing the protective film 150. The material and the formation method of the pressure-sensitive adhesive layer may be the same as the pressure-sensitive adhesive used for the PSA/adhesive layer 125.

The substrate of the protective film 150 may be a polyester film such as polyethylene terephthalate, polybutylene terephthalate and polyethylene naphthalate; or a polyolefin film such as polypropylene or polyethylene.

In the polarizing plate for OLED according to one embodiment of the present invention, the polarizer 110 may be disposed as the outmost layer after the protective film 150 is released.

The thickness of the protective film 150 may be 10 to 150 μm, preferably 25 to 130 μm. If the thickness of the protective film 150 is less than 10 μm, it may be difficult to release the protective film, and if the thickness exceeds 150 μm, the adhesion with the polarizer may be lowered.

Further, as shown in FIG. 5, the polarizing plate for OLED according to one embodiment of the present invention may have a release film 140 laminated on the opposite side of the viewing side of the pressure-sensitive adhesive layer 135.

The release film 140 is removed when the polarizing plate 100 is attached to the OLED panel 10.

The substrate of the release film 140 may be a polyester film such as polyethylene terephthalate, polybutylene terephthalate and polyethylene naphthalate; or a polyolefin film such as polypropylene or polyethylene.

In the substrate of the release film 140, the surface which contacts with the pressure-sensitive adhesive layer 135 may be release-treated. The release-treatment may be performed by a method of surface treatment using a release agent such as a silicone-based release agent, a fluorine-based release agent, and a long-chain alkyl grafted polymer-based release agent, or plasma treatment.

The thickness of the release film 140 may be 10 to 150 μm, preferably 25 to 130 μm. If the thickness of the release film 140 is less than 10 μm, it may be difficult to release the release film, and if the thickness exceeds 150 μm, the adhesion with the pressure-sensitive adhesive layer 135 may be lowered.

In the polarizing plate for OLED according to one embodiment of the present invention, the moisture barrier layer is laminated only on the opposite side of the viewing side, and thus the thinning of the polarizing plate is possible. Therefore, the total thickness thereof may be 100 μm or less, for example 20 to 90 μm, preferably 30 to 80 μm. Herein, the total thickness of the polarizing plate 100 for OLED is the thickness excluding the thickness of the protective film 150 and the release film 140.

One embodiment of the present invention relates to a display device comprising the polarizing plate for OLED.

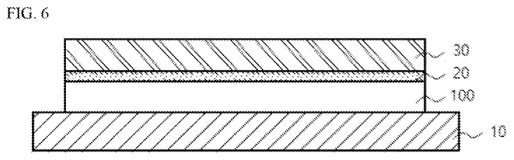

Referring to FIG. 6, the display device according to one embodiment of the present invention comprises the polarizing plate 100 for OLED; and an OLED panel 10 laminated on the opposite side of the viewing side of the polarizing plate 100 for OLED.

In addition, as shown in FIG. 6, the display device according to one embodiment of the present invention may comprise a cover window 30 attached on the viewing side of the polarizing plate 100 for OLED via a transparent adhesive layer 20.

The transparent adhesive layer 20 may comprise, for example, a pressure-sensitive adhesive (PSA)/adhesive such as an optically clear adhesive (OCA), an optically clear resin (OCR), etc.

The cover window 30 may be made of a material having durability against external impact and transparency for user visibility. For example, the cover window 30 may be a glass or a polymer film having flexibility. The glass may include a glass material in which flexible properties are implemented. Examples of the polymer film having flexibility may include polyimide (PI), polyethersulphone (PES), polyacrylate (PAR), polyetherimide (PEI), polyethylene napthalate (PEN), polyethylene terephthalate (PET), polyphenylene sulfide (PPS), polyarylate, polycarbonate (PC), cellulose triacetate (TAC), cellulose acetate propionate (CAP), and the like. The polymer film having flexibility may have a hard coating layer formed on at least one side thereof. The hard coating layer may be formed using the hard coating composition described above.

The display device according to one embodiment of the present invention may be an organic EL display device and may be in the form of a conventional flat panel display, flexible display or foldable display.

Hereinafter, the present invention will be described in more detail by way of Examples and Experimental Examples. However, these Examples and Experimental Examples are given for illustrative purposes only, and it is apparent to those skilled in the art that the scope of the invention is not intended to be limited by these Examples and Experimental Examples.

### Preparation Example 1: Preparation of Polarizer

A 20 μm-thick polyvinyl alcohol resin film (Kuraray Co., Ltd.) having an average degree of polymerization of about 2,400 and a degree of hydrolysis of 99.9 mol % or more was immersed in distilled water to swell it, and then was immersed in an aqueous solution of potassium iodide/boric acid/water in a weight ratio of 10/5/100 at 53° C. for 1 minute to be uniaxially stretched by about 5 times. Then, after washing with pure water of 15° C. for 1.5 seconds, it was dried at 50° C. for 5 minutes to obtain an 8 μm-thick polarizer in which iodine is adsorbed and aligned on polyvinyl alcohol.

### Preparation Example 2: Preparation of Water-Based Adhesive

3 parts by weight of fully saponified polyvinyl alcohol (Kuraray Co., Ltd., Kuraray Poval 117H), 3 parts by weight of acetacetyl-modified polyvinyl alcohol (Nippon Gohsei Chemical Co., Ltd., Gohsefimer Z-200), 0.18 parts by weight of zinc chloride (Nakaraitesk Co.), and 1.4 parts by weight of glyoxal (Nakaraitesk Co.) were dissolved in 100 parts by weight of water to obtain a water-based adhesive.

### Example 1: Manufacture of Polarizing Plate

According to the following method, a polarizing plate was manufactured with the same structure as in the embodiment of FIG. 3.

A 25 μm-thick COP film (water vapor transmission rate: 10 g/m²·24 hr) as a moisture barrier layer 120 was adhered onto the opposite side of the viewing side of the polarizer 110 prepared in Preparation Example 1, using the water-based adhesive of Preparation Example 2. At this time, the water-based adhesive was cured by drying in a 60° C. oven for 5 minutes.

A 2 μm-thick λ/2 retardation layer (discotic liquid crystal layer) 132 and an 1 μm-thick λ/4 retardation layer (nematic liquid crystal layer) 131 were adhered using a UV curable adhesive (ADEKA Corporation, KR-70T) to form a retardation layer 130. At this time, the UV curable adhesive was applied with the thickness of 2 μm and cured by irradiation with a metal halide lamp at a light integral of 250 mJ/cm².

The moisture barrier layer and the retardation layer were adhered via a pressure-sensitive adhesive (PSA)/adhesive layer 125. At this time, as the PSA/adhesive layer, a 5 μm-thick acrylic-based PSA (Lintec Corporation, #L2) was used.

A pressure-sensitive adhesive layer 135 was adhered onto the opposite side of the viewing side of the retardation layer. At this time, as the pressure-sensitive adhesive layer, a 15 μm-thick acrylic-based PSA (Lintec Corporation, #L1) was used.

### Example 2: Manufacture of Polarizing Plate

A polarizing plate was manufactured in the same manner as in Example 1, except that a 20 μm-thick acrylic film (water vapor transmission rate: 150 g/m²·24 hr) was used as the moisture barrier layer.

### Example 3: Manufacture of Polarizing Plate

A polarizing plate was manufactured in the same manner as in Example 1, except that a 40 μm-thick acrylic film (water vapor transmission rate: 100 g/m²·24 hr) was used as the moisture barrier layer.

### Example 4: Manufacture of Polarizing Plate

A polarizing plate was manufactured in the same manner as in Example 1, except that a 25 μm-thick TAC film (Toppan Co., Ltd., 25KCHC-TC, water vapor transmission rate: 450 g/m²·24 hr) in which a 7 μm-thick hard coating layer was formed on one side was used as the moisture barrier layer. At this time, the polarizer and the moisture barrier layer were adhered so that the hard coating layer was disposed on the opposite side of the polarizer.

### Example 5: Manufacture of Polarizing Plate

A polarizing plate was manufactured in the same manner as in Example 1, except that a 25 μm-thick TAC film (water vapor transmission rate: 400 g/m²·24 hr) in which a 2 μm-thick UV curable adhesive layer was formed on one side was used as the moisture barrier layer; and the polarizer and the moisture barrier layer were adhered via the UV curable adhesive layer without using a separate water-based adhesive. At this time, the UV curable adhesive layer was formed by applying a UV curable adhesive (ADEKA Corporation, KR-70T) with the thickness of 2 μm and curing by irradiation with a metal halide lamp at a light integral of 25 mJ/cm².

### Comparative Example 1: Manufacture of Polarizing Plate

A polarizing plate was manufactured in the same manner as in Example 1, except that a 25 μm-thick TAC film (water vapor transmission rate: 1,100 g/m²·24 hr) was used as the moisture barrier layer.

### Comparative Example 2: Manufacture of Polarizing Plate

A polarizing plate was manufactured in the same manner as in Example 1, except that a 40 μm-thick TAC film (water vapor transmission rate: 800 g/m²·24 hr) was used as the moisture barrier layer.

### Comparative Example 3: Manufacture of Polarizing Plate

A polarizing plate was manufactured in the same manner as in Example 1, except that a 60 μm-thick TAC film (water vapor transmission rate: 500 g/m²·24 hr) was used as the moisture barrier layer.

### Comparative Example 4: Manufacture of Polarizing Plate

A polarizing plate was manufactured in the same manner as in Example 1, except that a 25 μm-thick TAC film (water vapor transmission rate: 1,000 g/m²·24 hr) in which a 5 μm-thick pressure-sensitive adhesive layer was formed on one side was used as the moisture barrier layer; and the polarizer and the moisture barrier layer were adhered via the pressure-sensitive adhesive layer without using a separate water-based adhesive. At this time, the pressure-sensitive adhesive layer was formed using a pressure-sensitive adhesive (Lintec Corporation, #L2).

### Comparative Example 5: Manufacture of Polarizing Plate

A polarizing plate was manufactured in the same manner as in Example 1, except that a 25 μm-thick TAC film (water vapor transmission rate: 900 g/m²·24 hr) in which a 15 μm-thick pressure-sensitive adhesive layer was formed on one side was used as the moisture barrier layer; and the polarizer and the moisture barrier layer were adhered via the pressure-sensitive adhesive layer without using a separate water-based adhesive. At this time, the pressure-sensitive adhesive layer was formed using a pressure-sensitive adhesive (Lintec Corporation, #L1).

### Comparative Example 6: Manufacture of Polarizing Plate

A polarizing plate was manufactured in the same manner as in Example 1, except that the moisture barrier layer was adhered to the viewing side of the polarizer.

### Comparative Example 7: Manufacture of Polarizing Plate

A polarizing plate was manufactured in the same manner as in Example 1, except that the moisture barrier layers were adhered to both sides of the polarizer. At this time, a 25 μm-thick TAC film (Toppan Co., Ltd., 25KCHC-TC, water vapor transmission rate: 450 g/m²·24 hr) in which a 7 μm-thick hard coating layer was formed on one side was adhered onto the viewing side, and a 25 μm-thick COP film (water vapor transmission rate: 10 g/m²·24 hr) was adhered onto the opposite side of the viewing side.

### Comparative Example 8: Manufacture of Polarizing Plate

A polarizing plate was manufactured in the same manner as in Example 1, except that the layers were laminated in the order of the polarizer, the retardation layer and the moisture barrier layer.

### Comparative Example 9: Manufacture of Polarizing Plate

A polarizing plate was manufactured in the same manner as in Example 2, except that the layers were laminated in the order of the polarizer, the retardation layer and the moisture barrier layer.

### Comparative Example 10: Manufacture of Polarizing Plate

A polarizing plate was manufactured in the same manner as in Example 4, except that the layers were laminated in the order of the polarizer, the retardation layer and the moisture barrier layer.

### Experimental Example

The properties of the polarizing plates prepared in the Examples and Comparative Examples were measured by the following methods, and the results are shown in Table 1 below.

(1) Metal Corrosion Evaluation

The polarizing plate was cut into a size of 50 mm×50 mm, and a 500 μm-thick cover glass was adhered to the viewing side of the polarizer via an 150 μm-thick optically clear adhesive (3M Company). Thereafter, a polyethylene terephthalate (PET) film having an aluminum (Al) pattern layer was adhered onto the pressure-sensitive adhesive layer 135 of the polarizing plate to prepare a specimen.

The specimen was allowed to stand under the condition of 85° C. and 85% RH for 240 hours, and then the occurrence of corrosion was checked and evaluated according to the following evaluation criteria.

<Evaluation Criteria>

⊚: No change at all

∘: Corrosion occurred slightly

Δ: Corrosion occurred, but not turned completely transparent

x: Completely corroded and transparent

(2) Curl Property

The polarizing plate was cut into a size of 70 mm×150 mm and placed on a glass plate so that the pressure-sensitive adhesive layer 135 was disposed upward. After that, the polarizing plate was allowed to stand under the condition of 23° C. and 55% RH for 1 hour, and then the height of the highest portion from the glass plate was measured.

(3) Retardation Change

3 mL of water was loaded onto the polarizer of the polarizing plate and allowed to stand for 7 days. Thereafter, the water was removed, and then the change in the in-plane retardation (Ro) value was measured.

TABLE 1

| | | Metal | Curl | Retarda- |
|---|---|---|---|---|
| | Type of Moisture Barrier | Corrosion | Prop- | tion |
| | Layer | Evaluation | erty | Change |
| Example 1 | COP (25 μm) | ⊚ | 2.1 | 0 |
| Example 2 | Acrylic (20 μm) | ⊚ | 3.2 | −0.1 |
| Example 3 | Acrylic (40 μm) | ⊚ | 2.5 | −0.1 |
| Example 4 | TAC (25 μm) + hard coat- | ◯ | 3.0 | −0.3 |
| | ing layer | | | |
| Example 5 | UV curable adhesive | ◯ | 2.8 | −0.2 |
| | layer + TAC (25 μm) | | | |
| Com. Ex. 1 | TAC (25 μm) | X | 4.0 | −10 |
| Com. Ex. 2 | TAC (40 μm) | X | 3.9 | −11 |
| Com. Ex. 3 | TAC (60 μm) | Δ | 3.8 | −10 |
| Com. Ex. 4 | TAC (25 μm) + PSA layer | X | 5 | −9 |
| | (5 μm) | | | |
| Com. Ex. 5 | TAC (25 μm) + PSA layer | X | 6 | −8 |
| | (15 μm) | | | |
| Com. Ex. 6 | COP (25 μm) | X | 36 | −0.2 |
| Com. Ex. 7 | Hard coated TAC (25 μm)/ | ⊚ | 7.5 | −0.1 |
| | COP (25 μm) | | | |
| Com. Ex. 8 | COP (25 μm) | ⊚ | 3.0 | −9.5 |
| Com. Ex. 9 | Acrylic (20 μm) | ⊚ | 3.5 | −9.4 |
| Com. Ex. 10 | TAC (25 μm) + hard coat- | ◯ | 4.5 | −9.0 |
| | ing layer | | | |

As shown in Table 1, in the case of the polarizing plates of Examples 1 to 5 in which the moisture barrier layer having a water vapor transmission rate of 450 g/m²·24 hr or less was laminated only on the opposite side of the viewing side of the polarizer while having no moisture barrier layer on the viewing side, thereby having a structure where the polarizer is exposed as the outmost layer when the protective film is released, it was possible to suppress iodine migration from the polarizer to the lower panel, thereby preventing metal corrosion of the lower panel, and it was possible to prevent reverse curling of the polarizing plate and prevent the retardation change even in a high-humidity environment.

On the other hand, in the case of the polarizing plates of Comparative Examples 1 to 5 in which the moisture barrier layer having a water vapor transmission rate exceeding 450 g/m²·24 hr was laminated, the iodine migration from the polarizer to the lower panel was not prevented and thus metal corrosion of the lower panel occurred; it was difficult to prevent reverse curling of the polarizing plate; and the retardation change was large in a high-humidity environment. Further, in the case of the polarizing plates of Comparative Example 6 in which the moisture barrier layer was adhered to the viewing side of the polarizer, Comparative Example 7 in which the moisture barrier layers were adhered to both sides of the viewing side and the opposite side thereof, and Comparative Examples 8 to 10 in which the layers were laminated in the order of the polarizer, the retardation layer and the moisture barrier layer, it was difficult to prevent metal corrosion of the lower panel, reverse curling of the polarizing plate occurred, or the retardation change was large in a high-humidity environment.

Although specific parts of the present invention have been described in detail, it will be apparent to those skilled in the art that these specific descriptions are merely a preferred embodiment and that the scope of the present invention is not limited thereto. In addition, those skilled in the art will appreciate that various applications and modifications are possible, without departing from the scope and spirit of the invention based on the description above.

Therefore, the substantial scope of the present invention will be defined by the accompanying claims and their equivalents.

### DESCRIPTION OF REFERENCE NUMERALS

10: OLED panel
20: transparent adhesive layer
30: cover window
100: polarizing plate for OLED
110: polarizer
120: moisture barrier layer
125: PSA/adhesive layer
130: retardation layer
131: λ/4 retardation layer
132: λ/2 retardation layer
133: positive C plate layer
135: pressure-sensitive adhesive layer
140: release film
150: protective film

1. A polarizing plate for OLED in which a polarizer, a moisture barrier layer and a retardation layer are sequentially laminated,
wherein the moisture barrier layer is disposed on the opposite side of the viewing side of the polarizer, and has a water vapor transmission rate of 450 g/m²·24 hr or less; and
the retardation layer comprises a λ/4 retardation layer.

2. The polarizing plate for OLED of claim 1, wherein the moisture barrier layer is at least one film selected from the group consisting of: a cyclic olefin polymer film with or without at least one of a hard coating layer or a UV curable adhesive layer formed on at least one side thereof; an acrylic film with or without at least one of a hard coating layer or a UV curable adhesive layer formed on at least one side thereof; and a triacetyl cellulose film with at least one of a hard coating layer or a UV curable adhesive layer formed on at least one side thereof.

3. The polarizing plate for OLED of claim 1, wherein the moisture barrier layer has an in-plane retardation (Ro) of 10 μm or less.

4. The polarizing plate for OLED of claim 1, wherein the moisture barrier layer has an out-of-plane retardation (Rth) of 40 μm or less.

5. The polarizing plate for OLED of claim 1, wherein the retardation layer is a λ/4 retardation layer; a retardation layer in which a λ/2 retardation layer and a λ/4 retardation layer are laminated sequentially from the viewing side; or a retardation layer in which a λ/4 retardation layer and a positive C plate layer are laminated sequentially from the viewing side.

6. The polarizing plate for OLED of claim 1, wherein the moisture barrier layer and the retardation layer are attached via a pressure-sensitive adhesive or an adhesive layer.

7. The polarizing plate for OLED of claim 1, further comprising a pressure-sensitive adhesive layer laminated on the opposite side of the viewing side of the retardation layer.

8. The polarizing plate for OLED of claim 1, wherein a releasable protective film is laminated on the viewing side of the polarizer.

9. The polarizing plate for OLED of claim 7, further comprising a release film laminated on the opposite side of the viewing side of the pressure-sensitive adhesive layer.

10. A display device, comprising:
the polarizing plate for OLED of claim 1; and
an OLED panel laminated on the opposite side of the viewing side of the polarizing plate for OLED.

11. A display device, comprising:
the polarizing plate for OLED of claim 1;
an OLED panel laminated on the opposite side of the viewing side of the polarizing plate for OLED; and
a cover window attached on the viewing side of the polarizing plate for OLED via a transparent adhesive layer.

12. A display device, comprising:
the polarizing plate for OLED of claim 2; and
an OLED panel laminated on the opposite side of the viewing side of the polarizing plate for OLED.

13. A display device, comprising:
the polarizing plate for OLED of claim 3; and
an OLED panel laminated on the opposite side of the viewing side of the polarizing plate for OLED.

14. A display device, comprising:
the polarizing plate for OLED of claim 4; and
an OLED panel laminated on the opposite side of the viewing side of the polarizing plate for OLED.

15. A display device, comprising:
the polarizing plate for OLED of claim 5; and
an OLED panel laminated on the opposite side of the viewing side of the polarizing plate for OLED.

16. A display device, comprising:
the polarizing plate for OLED of claim 6; and
an OLED panel laminated on the opposite side of the viewing side of the polarizing plate for OLED.

17. A display device, comprising:
the polarizing plate for OLED of claim 7; and
an OLED panel laminated on the opposite side of the viewing side of the polarizing plate for OLED.

18. A display device, comprising:
the polarizing plate for OLED of claim 8; and
an OLED panel laminated on the opposite side of the viewing side of the polarizing plate for OLED.
